(19) United States
(12) Patent Application Publication
(10) Pub. No.: US 2009/0224139 A1
(43) Pub. Date: Sep. 10, 2009

(54) Drift Field Demodulation Pixel with Pinned Photo Diode

(75) Inventors: Bernhard Buettgen, Adliswil (CH); Michael Lehmann, Winterthur (CH); Jonas Felber, Windisch (CH)

Correspondence Address: HOUSTON ELISEEVA, 4 MILITIA DRIVE, SUITE 4, LEXINGTON, MA, 02421, US

(73) Assignee: MESA Imaging AG, Zurich (CH)

(21) Appl. No.: 12/397,825

(22) Filed: Mar. 4, 2009

Related U.S. Application Data
(60) Provisional application No. 61/033,501, filed on Mar. 4, 2008.

(51) Int. Cl. H01L 27/00; H04N 13/04

(52) U.S. Cl. 250/208.1; 348/51; 348/E13.001

(57) ABSTRACT

A pixel based on a pinned-photodiode structure that creates a lateral electric drift field. The combination of the photodiode with adjacent CCD gates enables the utilization of the drift field device in applications such as 3-D imaging. Compared with recently used demodulation devices in CCD or CMOS technology, the new pinned-photodiode based drift field pixel has its advantages in its wide independence of the quantum efficiency on the optical wavelength, its high optical sensitivity, the opportunity of easily creating arbitrary potential distributions in the semiconductor, the straight-forward routing capabilities and the generation of perfectly linear potential distributions in the semiconductor.

### RELATED APPLICATIONS

This application claims the benefit under 35 USC 119(e) of U.S. Provisional Application No. 61/033,501, filed on Mar. 4, 2008, which is incorporated herein by reference in its entirety.

### BACKGROUND OF THE INVENTION

The demodulation of modulated light signals at the pixel level requires the switching of a photo-generated charge. While it is possible to use either photo-generated electrons or holes, typical solutions use photo-generated electrons because of their higher mobility in the semiconductor material. Some pixel architectures do the necessary signal processing based on the photo-current whereas other architectures work in the charge domain directly.

Common to all pixels is the necessity to transfer charges through the photo-sensitive detection region to a subsequent storage area and/or to a subsequent processing unit. In the case of charge-domain based pixel architectures, the photo-charges are generally transferred to a storage or integration node. In order to demodulate an optical signal, the pixel has to have at least one integration node that can be controlled to accumulate the photo-generated charges during certain time intervals, typically synchronously with a modulated illumination signal.

Different pixel concepts have been realized in the last few decades. Many use a demodulation pixel, which transfers the photo-generated charge below a certain number of adjacent poly-silicon gates to discrete accumulation capacitances. Spirig, “Apparatus and method for detection of an intensity-modulated radiation field”, Jan. 5, 1999, U.S. Pat. No. 5,856,667 disclosed a charge coupled device (CCD) lock-in concept that allows the in-pixel sampling of the impinging light signal with theoretically an arbitrary number of samples. Another very similar pixel concept has been demonstrated by T. Ushinaga et al., “A QVGA-size CMOS time-of-flight range image sensor with background light charge draining structure”, Three-dimensional image capture and applications VII, Proceedings of SPIE, Vol. 6056, pp. 34-41, 2006, where a thick field-oxide layer is used to smear the potential distribution below the demodulation gates.

A common problem of the afore-mentioned pixel approaches is the slowness of the charge transport through the semiconductor material, which undermines significantly the quality of the in-pixel demodulation process. In all pixel structures, the limiting transport speed is the step-shaped potential distribution in the semiconductor substrate. Ideally, the potential distribution decreases linearly in lateral direction giving rise to the lateral electric fields that are preferably used to transport the charges through the semiconductor in direction to the different storage sites. Step-shaped potential distributions created by gate structures have regions with flat lateral potential distribution, where slow thermal diffusion processes dominate the transport speed instead of the lateral electric drift fields.

New pixel designs have been explored in recent years that are intended to accelerate the in-pixel transport of the charges by exploiting lateral electric drift fields. Seitz, “Four-tap demodulation pixel”, filed on Jun. 20, 2002, GB 2 389 960 A, invented the first drift field demodulation device for photo detection purposes. It is based on a very high-resistive photo-transparent poly-silicon gate electrode. It even allows the design of pixels having an arbitrary number of n samples. The static drift field pixel disclosed by Büttgen, “Device and method for the demodulation of modulated electromagnetic wave fields”, European Patent Application, Publication date: Feb. 8, 2006, EP1777747A1—in contrast to the architectures mentioned before—clearly separates the detection and the demodulation regions within the pixel. It shows lower power consumption compared to the drift field demodulation approach of Seitz and, at the same time, supports fast in-pixel lateral charge transport. Another pixel concept was proven by D. van Nieuwenhove et al., Novel Standard CMOS Detector using Majority Current for guiding Photo-Generated Electrons towards Detecting Junctions”, Proceedings Symposium IEEE/LEOS Benelux Chapter, 2005. In this pixel architecture the lateral electric drift field is generated by the current of majority carriers within the semiconductor substrate. Minority carriers are generated by the photons and transported to the particular side of the pixel just depending on the applied drift field.

One major application of demodulation pixels is found in real-time 3-D imaging. By demodulating the optical signal and applying the discrete Fourier analysis on the acquired samples, parameters such as amplitude and phase can be extracted for the frequencies of interest. If the optical signal is sinusoidally modulated, capturing at least three discrete samples enables the extraction of the offset, amplitude and phase information. In a time-of-flight 3D imaging system, the phase value corresponds proportionally to the sought distance value. Such a harmonic modulation scheme is often used in real-time 3-D imaging systems incorporating the demodulation pixels.

The precision of the pixel-wise distance measurement is determined by the in-pixel transfer time needed for the electrons to pass from the photosensitive region in which they are generated to the area where they are accumulated or post-processed The ability of the pixel to sample at high modulation frequencies is determined by the transit time and is of high importance to perform distance measurements with high accuracy. The achievable measurement accuracy is directly inversely proportional to the modulation frequency.

### SUMMARY OF THE INVENTION

Each of the three major concepts of drift field pixels has its particular drawbacks restricting the 3-D imaging applications.

The drift field demodulation pixel generates the lateral drift field by a constant electronic current through the poly-silicon gate. In order to reduce the power consumption, the gate is suggested to be as resistive as possible. However, the creation of sensors with large pixel counts is not possible without increasing the sensor's power consumption. The high in-pixel power consumption has also a negative impact on the thermal heating of the sensor and hence, on its dark current noise.

The drift field pixel of Nieuwenhoven generates the drift field in the substrate by the current flow of majority carriers. One major problem of this pixel concept is the self-heating of the pixel and the associated dark current noise. Furthermore, the quantum efficiency suffers from the fact that the same semiconductor region is used to create the drift field by a current of majority carriers and to separate the minority carriers. High recombination rates are the result, which reduces the optical sensitivity.

The static drift field pixel requires the creation of a large region having a lateral electric drift field that moves the charges in the direction of the demodulation region. The drift region is currently implemented as a successive, overlapping CCD gate structures. Each gate has a minimum width and the gate voltages are linearly increasing in the direction of the demodulation region. The voltages applied to the gates are all constant meaning that the lateral electric drift field is also constant. The main drawback is the complex layout, in particular the connection of the large number of gates to the constant voltages. Even more dramatically, if a pure CCD process is used, the routing rules are more restricting than in a complimentary metal oxide semiconductor (CMOS) process with CCD option generally making such a design more impractical.

Another drawback of the static drift field pixel layout is the high number of overlaps between poly-silicon gates leading to optical interference and, hence, to a reduced quantum efficiency strongly depending on the wavelength. Furthermore, the gate structure is not perfectly suited to create perfectly linear potential distributions, which undermines the charge transport speed in the lateral direction.

In order to overcome the complex pixel design, to reduce the necessary number of gates in the detection region, to reduce the power consumption and to increase the optical sensitivity, the following pixel implementation with a pinned-photo diode architecture is proposed for high-speed charge transfer and 3-D imaging applications. The pinned photodiode architecture means the possibility to implant p on n on p. Thus, standard CMOS processes that provide such an implantation set-up are preferably used. In general, CCD processes do not offer this feature of pinned photodiodes.

In general, according to one aspect, the invention features a pixel for an optical sensor, comprising: at least one sense node for receiving photo-generated charges and a pinned photodiode structure for creating a lateral drift field for transferring the photo-generated charges created in a photosensitive region to the at least two sense nodes.

In general, according to another aspect, the invention features a 3-D imaging system comprising a modulated light source of illuminating a scene with modulated light and an imaging sensor for detecting the modulated light from the scene. The imaging sensor comprises a two-dimensional array of pixels, the pixels each including at least one sense node for receiving photo-generated charges generated by the detected modulated light and a pinned photodiode structure for creating a lateral drift field for transferring the photo-generated charges created in a photosensitive region to the at least two sense nodes synchronously with a modulation of the modulated light.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a schematic cross-sectional view of a pinned photo diode architecture generating a linear potential gradient within the substrate;

FIG. 2 is a schematic cross-sectional view of a pinned photo diode architecture with two gates that establish the potential drop within the depleted PPD region and across the photosensitive region;

FIG. 3 is a schematic cross-sectional view of a pinned photo diode architecture providing a modulated drift field to move photo-generated charge selectively to one of two toggle gates;

FIG. 4 is a top view showing the pinned photo diode architecture of FIG. 3;

FIG. 5 is a top view showing the pinned photo diode architecture providing four taps per pixel;

FIG. 6 is a schematic cross-sectional view of pinned photo diode architecture in a static lateral electric drift field that moves charges to the subsequent post-processing region where the photo-generated charges are read out;

FIG. 7 is a top view showing pinned photo diode architecture in a static lateral electric drift field and the post-processing region;

FIG. 8 shows a conventional scheme of the three-dimensional-measurement set-up using a sensor comprising demodulation pixels; and

FIGS. 9A and 9B are plots representing the optical intensity and the charge flow as a function of the time for the emitted signal and the received signal, respectively, using the scheme of FIG. 1.

### DETAILED DESCRIPTION OF THE PREFERRED EMBODIMENTS

In the following descriptions, we use just p doped substrates in order to keep the descriptions clear and well-structured. However, the devices are not limited to p-doped substrates. In the case that n-doped material is used as substrate, all doping concentrations and considerations of the potential distributions are reversed, which, however, does not mean that any functioning of the device would be restricted.

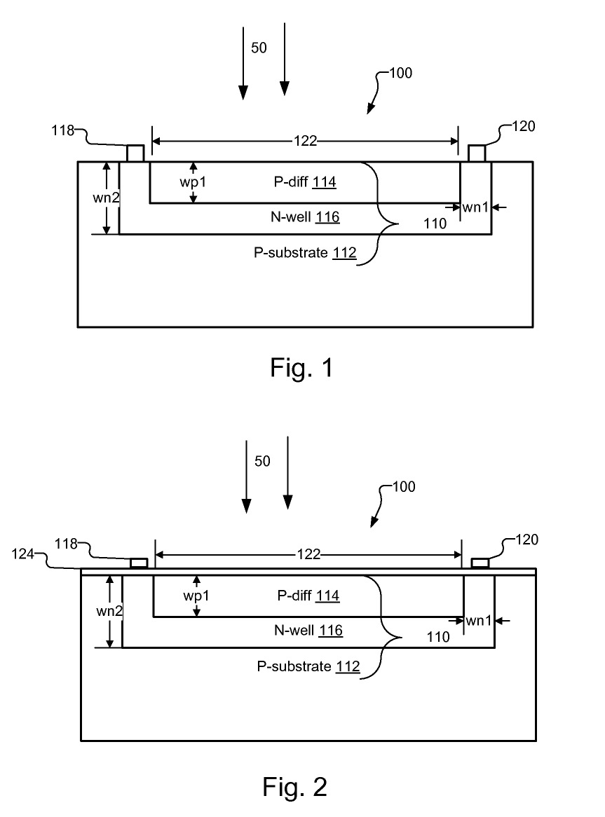

FIG. 1 shows the basic idea of a gate-less static drift field pixel 100 based on a pinned photodiode (PPD) structure. A pnp structure 110 is created, which is fully depleted when the two p-layers, p-doped substrate 112 and p-doped diffusion layer 114 are connected to the same potential and the sandwiched n-well layer 116 is set to a potential greater or equal the built-in voltage.

In the case that two different voltages are applied to the left (low potential) contact 118 and right (high potential) contact 120 to the n-well layer of the PPD structure 110, a constantly increasing potential is created moving from left to right, in the figure. This lateral electric field is used to transport photo-generated charges created in a photosensitive region 122 to the right side or in the direction of the high potential contact 120. These charges are generated by incoming light 50 in the PPD structure 110.

In order to avoid direct charge drain by the high-voltage contact 120, this contact needs to be replaced by an insulated gate, such as a poly-silicon gate.

FIG. 2 shows a static drift field pixel 100 using insulated gate structures with the basic PPD device 110 with two gates 118/120 on the left and right side to generate the lateral electric drift field inside the depletion region of the semiconductor substrate 114 and laterally within the photosensitive region 122.

Specifically, an insulating layer 124 is deposited over the substrate 114. In the preferred embodiment, the insulating layer is silicon dioxide. The insulating layer separates the low potential contact 118 and the high potential contact 120 from the substrate so they are electrically insulated from the substrate 114 to create the insulated gate structures.

The use of the poly-silicon gate structures means that the voltage at the silicon-insulator interface is created by the capacitive coupling between the contacts/gates 118, 120 and the substrate 114, similar to the principle in charge coupled devices (CCDs).

Three advantages of this drift field region are highlighted below, all due to the fact that no gates are needed in the photosensitive region 122:

1. The layout is less complicated. The number of necessary contacts is smaller and the routing does not have to be accomplished for a few tens of gate signals.

2. The quantum efficiency is higher than it is for a CCD-gate based structure. The quantum efficiency curve exhibits less fluctuations because there are less interferences between overlapping gates.

3. The structure is suited to generate perfect linearized potential distributions in the semiconductor material without increasing the in-pixel routing effort.

Demodulation Pixel DP Designs

Below, examples of two different demodulation devices are described based on the PPD. The first one is based on modulated drift fields and the second one on static drift fields.

Modulated Drift Field

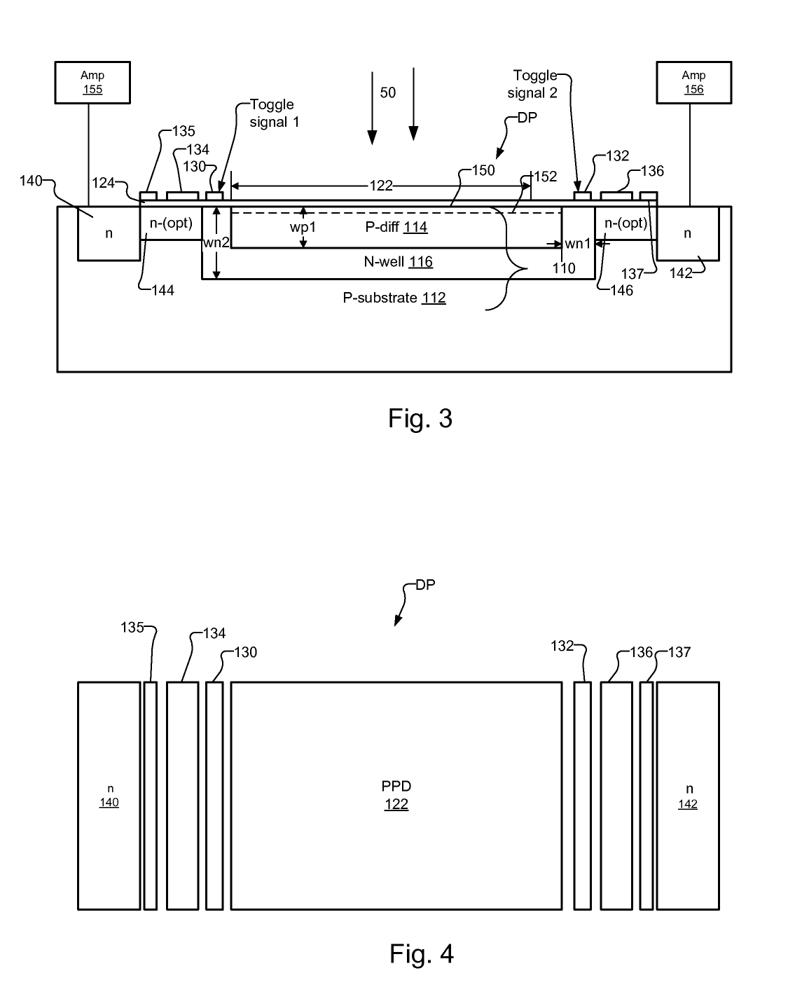

FIG. 3 is an example of a cross section through a modulated drift field pixel DP based on PPD structure 110. By controlling the left and right toggle gates dynamically, such that a high potential is applied to one and a low potential applied to the other of the toggle gates 130/132 and then reversing the potentials such that the low potential is applied to one and the high potential applied to the other of the toggle gates 132/130, the drift field in the photosensitive region 122, which is created by the PPD structure 110, is modulated and the charge generated by optical incidence 50 is transferred to alternately to the left side and the right side.

On both sides of the pixel DP, the photo-generated charge are first stored or integrated below the respective integration gates 134/136. Each integration gate 134/136 is decoupled from a corresponding diffusion sense node 140/142 by an additional out gate 135/137. The integration gates 134/136 and out gates 135/137 structure, however, is optional meaning that the charge can be directly stored in the diffusion nodes 140/142 in some implementations.

Preferably, an n-implant 144/146 is formed below each of the integration gates 134/136 and out gates 135/137.

Also, in a preferred embodiment, a charge transfer channel 152 is provided that is shifted from the substrate-insulator interface 150 downwards into the substrate 114 to form a so-called buried channel. The buried channel provides higher charge transfer efficiency and less trapping noise.

Typically, amplifiers 155/156 inside the pixel DP are used to read out of the photo-generated charge. Usually, standard source followers are used in imaging devices in order to save space for the photo-sensitive region.

FIG. 4 is a top view of the two gate modulated drift field sensor based on PPD structure. The demodulation pixel DP delivers two samples of the impinging optical signal that is converted in the photo-sensitive region 122. The charged is transferred alternately in the direction of each of the two toggle gates 130/132. Then during a readout phase, charge integrated in the integration gates 134/136 is transferred through the out gates 135/137 to the corresponding diffusion sense nodes 140/142.

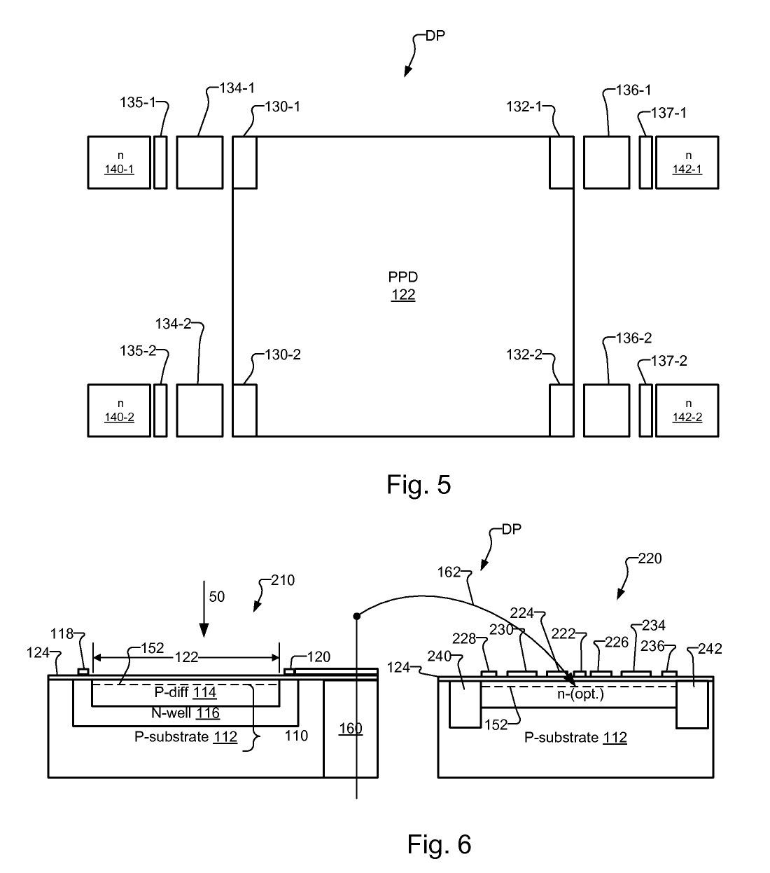

FIG. 5 is top view of the four gate modulated drift field sensor with the PPD toggle gates 130-1, 130-2, 132-1, 132-2 located on the four corners of the PPD in the photosensitive region 122. Also the integration gate structures 134-1, 134-2, 136-1, 136-2, out gate structures 135-1, 135-2, 137-1, 137-2 and the diffusion nodes 140-1, 140-2, 142-1, 142-2 are added to each corner This pixel is able to deliver four samples of the impinging optical signal at the same time.

Static Drift Field with Subsequent Demodulation Region

The static drift field demodulation pixel DP includes two parts, the drift field section 210 and a demodulation section 220 for post-processing, memory and/or readout.

In the preferred embodiment of FIG. 6, the PPD structure 110 is located in the photosensitive region 122 in the drift field section 210. It is used to generate the static lateral drift field to move photo-generated charges to the high potential contact 120. A constant low potential is applied to the left gate 118 and a constant high potential is applied to the right gate 120. The photo-generated charges are then transferred from transfer region 160 via an electrical connection 162 to a dedicated demodulation section 220 for post-processing, memory and/or readout.

The demodulation section 220 comprises a middle gate 222, two toggle gates 224/226 to the left and right side of the middle gate 222. By applying changing voltages to the two toggle gates 224/226, charges are can alternately be moved either to a left side integration gate 230 or a right side integration gate 234. Each of the left side integration gate 230 or right side integration gate 234 has a corresponding out gate, out gate 228 and out gate 236, respectively, that control the movement of the photo-generated charges from the left side integration gate 230 or the right side integration gate 234 to the left side diffusion sense node 240 or right side diffusion sense node 242, respectively

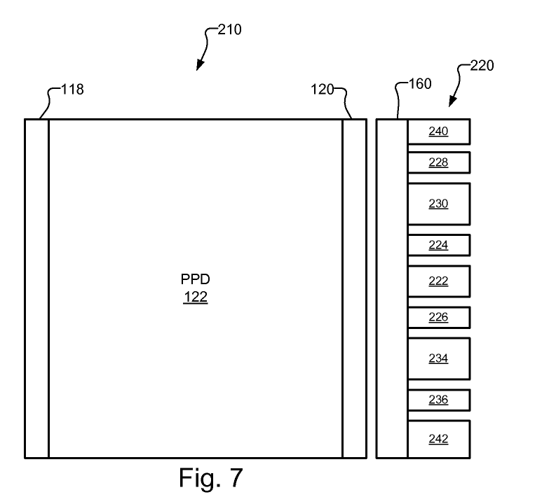

FIG. 7 is a top view of the two-dimensional pixel structure having a static drift field with subsequent demodulation region. Photo-generated charges created in the large PPD section are moved by the static drift field toward the high potential contact 120 and then through the transfer region 160 to the demodulation region 220. Here, the charges are transferred to either diffusion sense node 240/242 by the gate structure 222, 224, 226, 228, 230, 234, 236. In other embodiments, the static field demodulation pixel DP uses a 4 sense node configuration similar to the embodiment as illustrated in FIG. 5

### SUMMARY

A new drift field pixel is disclosed, which is based on the fundamental structure of a pinned-photodiode. With regard to functionally comparable CCD or CMOS devices, the main advantages are:

High photo-sensitivity

Independence of the photo-sensitivity on wide ranges of the optical wavelength

Simplified layout

Perfect linear lateral drift fields

The device is suited to be manufactured in standard CMOS processes of even smallest feature sizes. In particular, 3-D imaging applications, described below, can be realized with that device because the perfect linearity of the drift fields leads to best-achievable demodulation performances.

3D-Measurement Camera System Using the Pixels

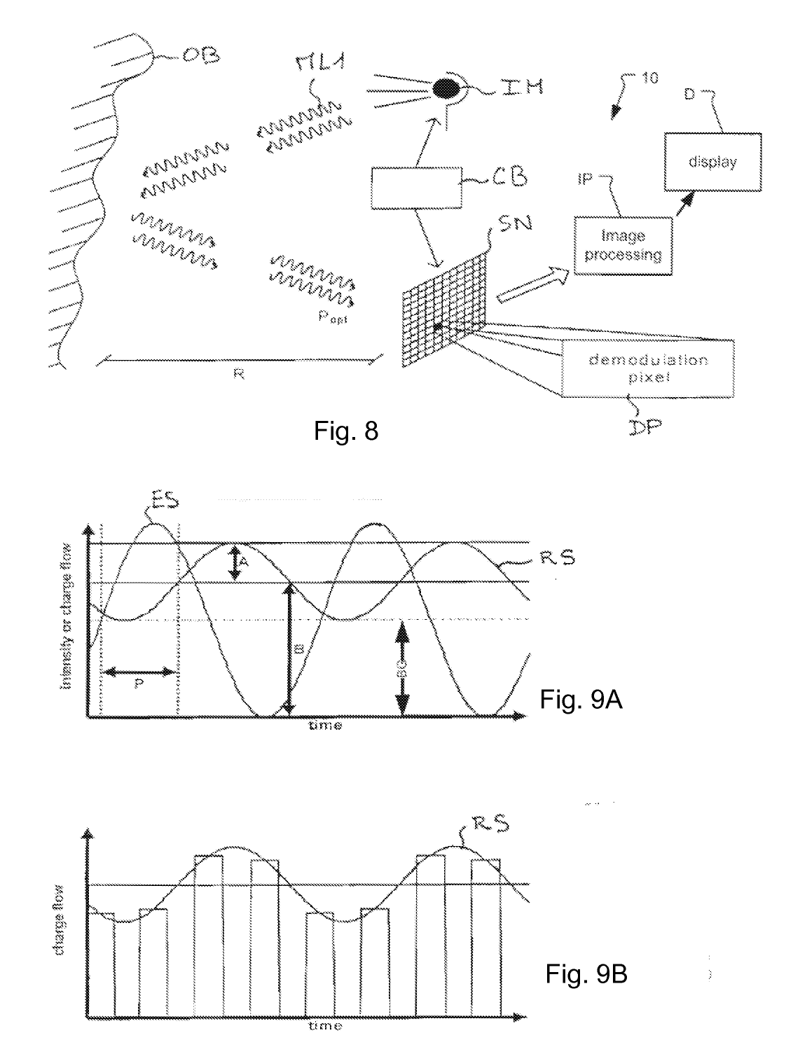

FIG. 8 illustrates the basic principle of a 3D-measurement camera system based on the demodulation pixels DP described above.

Modulated illumination light ML1 from an illumination module or light source IM is sent to the object OB of a scene. A fraction of the total optical power sent out is reflected to the camera 10 and detected by the 3D imaging sensor SN. The sensor SN comprises a two dimensional pixel matrix of the demodulation pixels DP. Each pixel DP is capable of demodulating the impinging light signal as described above. A control board CB regulates the timing of the camera 10. The phase values of all pixels correspond to the particular distance information of the corresponding point in the scene. The two-dimension gray scale image with the distance information is converted into a three-dimensional image by image processor IP. This can be displayed to a user via display D or used as a machine vision input.

The distance R for each pixel is calculated by

R=(c*TOF)/2,

with c as light velocity and TOF corresponding to the time-of-flight. Either pulse intensity-modulated or continuously intensity-modulated light is sent out by the illumination module or light source IM, reflected by the object and detected by the sensor. With each pixel of the sensor being capable of demodulating the optical signal at the same time, the sensor is able to deliver 3D images in real-time, i.e., frame rates of up to 30 Hertz (Hz), or even more, are possible. In pulse operation the demodulation would deliver the time-of-flight directly. However, continuous sine modulation delivers the phase delay (P) between the emitted signal and the received signal, also corresponding directly to the distance R:

R=(P*c)/(4*pi*fmod),

where fmod is the modulation frequency of the optical signal.

FIGS. 9A and 9B show the relationship between signals for the case of continuous sinusoidal modulation and the signal sampling. Although this specific modulation scheme is highlighted in the following, the utilization of the pixel in 3D-imaging is not restricted to this particular scheme. Any other modulation scheme is applicable: e.g. pulse, rectangular, pseudo-noise or chirp modulation. Only the final extraction of the distance information is different.

FIG. 9A shows both the modulated emitted illumination signal ES and received signal RS. The amplitude A, offset B of the received signal RS and phase P between both signals are unknown, but they can be unambiguously reconstructed with at least three samples of the received signal. BG represents the received signal part due to background light.

In FIG. 9B, a sampling with four samples per modulation period is depicted. Each sample is an integration of the electrical photo-signal in the integration gates or diffusion regions described above over a duration dt that is a predefined fraction of the modulation period. In order to increase the signal to noise ratio of each sample the photo-generated charges may be accumulated over several—up to more than 1 million—modulation periods in the integration gates.

By activating the PPD structures and demodulation sections, alternately the photogenerated charge injected into the demodulation section is transferred to the specific storage site or integration gate. The alternation of the PPD structures as described with respect to FIGS. 3 and 4 or the demodulation section 220 of FIGS. 6 and 7 is done synchronously with the sampling frequency and the modulated light from source ML1.

The electronic timing circuit, employing for example a field programmable gate array (FPGA), generates the signals for the synchronous channel activation in the demodulation stage. During the activation of one conduction channel, injected charge carriers are moved to the corresponding integration gate. As example, only two conduction channels are implemented in the demodulation region. Assuming there is no background light BG (i.e., A=BG), then two samples A0 and A1 of the modulation signal sampled at times that differ by half of the modulation period, allow the calculation of the phase P and the amplitude A of a sinusoidal intensity modulated current injected into the sampling stage. The equations look as follows:

A=(A0+A1)/2

P=arcsin [(A0−A1)/(A0+A1)].

Extending the example to four conduction channels and sample values requires in practice a different gate structure of the demodulation region with four contacts and four integration regions and an appropriate clocking scheme for the electrode voltages in order to obtain four sample values A0, A1, A2 and A3 of the injected current. Generally the samples are the result of the integration of injected charge carriers over many quarters of the modulation period, whereby finally each sample corresponds to a multiple of one quarter of the modulation period. The phase shift between two subsequent samples is 90 degree.

Instead of implementing the four channels, one can also use two channels only, but adding a second measurement with the light source delayed by 90 degrees in order to get again the four samples.

Using these four samples, the three decisive modulation parameters amplitude A, offset B and phase shift P of the modulation signal can be extracted by the equations

A=sqrt[(A3−A1)̂2+(A2−A1)̂2]/2

B=[A0+A1+A2+A3]/4

P=arctan [(A3−A1)/(A0−A2)]

While this invention has been particularly shown and described with references to preferred embodiments thereof, it will be understood by those skilled in the art that various changes in form and details may be made therein without departing from the scope of the invention encompassed by the appended claims.

What is claimed is:

1. A pixel for an optical sensor, comprising:
at least one sense node for receiving photo-generated charges; and
a pinned photodiode structure for creating a lateral drift field for transferring the photo-generated charges created in a photosensitive region to the at least one sense node.

2. A pixel as claimed in claim 1, further comprising at least two toggle gates establishing an alternating drift field by pinned photodiode structure that transfers the photo-generated charges alternately between at least two of the sense nodes.

3. A pixel as claimed in claim 1, further comprising a demodulation section wherein the pinned photo diode structure transfers the photo-generated charges to the demodulation section, which transfers further the photo-generated charge alternately to the at least two sense node.

4. A pixel as claimed in claim 1, wherein the pinned photo diode structure comprises a substrate of a first conductivity type, a well of a second conductivity type, and a diffusion of the first conductivity type.

5. A pixel as claimed in claim 4, further comprising at least two toggle gates for establishing a potential across the pinned photo diode structure.

6. A pixel as claimed in claim 1, further comprising integration gates for the sense nodes, the integration gates receiving the photo-generated charges prior to transfer to the sense nodes.

7. A pixel as claimed in claim 6, further comprising out gates between the sense nodes and the integration gates for transferring the photo-generated charges to the sense nodes.

8. A 3-D imaging system comprising:
a modulated light source of illuminating a scene with modulated light; and
an imaging sensor for detecting the modulated light from the scene, the imaging sensor comprising a two-dimensional array of pixels, the pixels each including:
at least one sense node for receiving photo-generated charges generated by the detected modulated light; and
a pinned photodiode structure for creating a lateral drift field for transferring the photo-generated charges created in a photosensitive region to the at least one sense node synchronously with a modulation of the modulated light.

9. A system as claimed in claim 8, wherein the pixels each include at least two toggle gates establishing an alternating drift field by pinned photodiode structure that transfers the photo-generated charges alternately between two of the sense nodes.

10. A system as claimed in claim 8, wherein the pixels each include a demodulation section wherein the pinned photo diode structure transfers the photo-generated to the demodulation section, which transfers to the photo-generated charge alternately to the at least one sense node.

11. A system as claimed in claim 8, wherein the pinned photo diode structure of the pixels comprises a substrate of a first conductivity type, a well of a second conductivity type, and a diffusion of the first conductivity type.

12. A system as claimed in claim 11, wherein the pixels each include at least two toggle gates for establishing a potential across the pinned photo diode structure.

13. A system as claimed in claim 8, wherein the pixels each include integration gates for the sense nodes, the integration gates receiving the photo-generated charges prior to transfer to the sense nodes.

14. A system as claimed in claim 13, wherein the pixels each include out gates between the sense nodes and the integration gates for transferring the photo-generated charges to the sense nodes.
